(19) United States
(12) Patent Application Publication
(10) Pub. No.: US 2020/0372842 A1
(43) Pub. Date: Nov. 26, 2020

(54) LED DISPLAY SCREEN CAPABLE OF PREVENTING THE DISPLAY MODULE FROM ACCIDENTALY FALLING OFF

(71) Applicant: DARKLIGHT TECHNOLOGY LTD, Shenzhen (CN)

(72) Inventors: Kaihuan GUAN, Shenzhen (CN); Hui YANG, Shenzhen (CN)

(73) Assignee: DARKLIGHT TECHNOLOGY LTD

(21) Appl. No.: 16/737,746

(22) Filed: Jan. 8, 2020

(30) Foreign Application Priority Data
May 22, 2019 (CN) 201910426539.6

(51) Int. Cl. G09F 9/302; H01L 25/075; G06F 1/16; H01L 33/24

(52) U.S. Cl. CPC G09F 9/3026; H01L 33/24; G06F 1/1607; H01L 25/0753

(57) ABSTRACT

The present invention relates to an LED display screen capable of preventing the display module from accidentally falling off. The LED display screen comprises a fixing frame and a plurality of display modules. The removable structures are arranged between each of the display modules and the fixing frame, at the same time, protection structures are disposed between each of the display modules and the fixing frame. The protection structures comprises plugs and sockets, when the protection structures are in locking state, the plugs are inserted into the sockets and locked in the sockets, so that the display modules do not accidentally fall off from the fixing frame, and prevent from being stolen. When the protection structures are in opening state, the plugs are extracted from the sockets, and there is no connection between the plugs and the sockets, and then the display modules can be easily and quickly removed from the fixing frame by the removable structures, so that realize the easy disassembling.

### BACKGROUND OF THE PRESENT INVENTION

### Field of Invention

The present invention relates to an LED display screen, in particular to an LED display screen capable of preventing the display module from accidentally falling off.

### Description of Related Arts

As shown in FIG. 1, the conventional LED display screen generally comprises a box 1 and an LED display module 2. When used, a plurality of LED display modules 2 are simultaneously assembled and fixed on the box 1 to form a large LED display screen.

As for the conventional LED display, the LED display module 2 is fixed and locked on the box 1 by screws, but the assembling in this method is very complicated, and in addition, after the assembling is completed, once the specific LED display module is failed, the removing and replacement are also very inconvenient.

In order to overcome the above disadvantages, some LED display screens are provided with a removable structure 3, and the typical removable structure 3 is a magnetic structure, a clamping slot, a clamping post, and the like. A plurality of LED display modules 2 are simultaneously assembled and fixed on the box 1 by the removable structure 3. At the same time, removing and replacing the specific LED display module is also extremely simple.

However, since the feature of the removable structure 3 is that it is easy to assemble and disassemble, the connection is not very stable. In practice, when such an LED display screen is provided in outdoors, it is often affected by wind and rain. The display module 2 may be blown off from the box 1, thereby bring a great security risk. In order to eliminate such security risk, some manufacturers additionally set some wires, and each LED display module 2 is bound on the box 1 to achieve a security protection, but in this manner, the products are inconvenient to be assembled and disassembled, and this is the main disadvantage of the traditional technology.

### SUMMARY OF THE PRESENT INVENTION

The invention provides an LED display screen capable of preventing the display module from accidentally falling off, comprising a fixing frame (10) and a plurality of display modules (20). A removable structure (30) is disposed between each of the display module (20) and the fixing frame (10), at the same time, a protection structure (100) is disposed between each of the display modules (20) and the fixing frame (10). The protection structure (100) can improve the stability of the assembling of the display module (20), and prevent the display module (20) from falling off by the external force. In addition, only by some special tools, can the protection structure (100) be opened and the display module (20) be removed, and then the display module can be prevented from being stolen, which is the main object of the present invention.

An LED display screen capable of preventing the display module from accidentally falling off comprising a fixing frame (10) and a plurality of display modules (20), wherein a removable structure (30) is disposed between each of the display module (20) and the fixing frame (10), and the removable structure (30) comprises a fixing frame connector (31) disposed on the fixing frame (10) and a module connector (32) disposed on the display module (20) corresponding to the fixing frame connector (31).

At the same time, a protection structure (100) is disposed between each of the display module (20) and the fixing frame (10), which comprises a plug (200) fixed on the fixing frame (10) and a socket (300) fixed on the display module (20), and the plug (200) has a one-to-one correspondence with the socket (300).

### BRIEF DESCRIPTION OF THE DRAWINGS

FIG. 1 is a schematic view of a conventional LED display screen.

FIG. 2 is a perspective view of the present invention.

FIG. 3 is a perspective view of a protection structure of the present invention.

FIG. 4 is a sectional view of a protection structure of the present invention.

FIG. 5 is a view of the position of the magnetic detaching piece of the present invention.

FIG. 6 is a schematic view of the operation principle of the present invention.

FIG. 7 is a schematic view of the working principle of the present invention.

### DETAILED DESCRIPTION OF THE PREFERRED EMBODIMENT

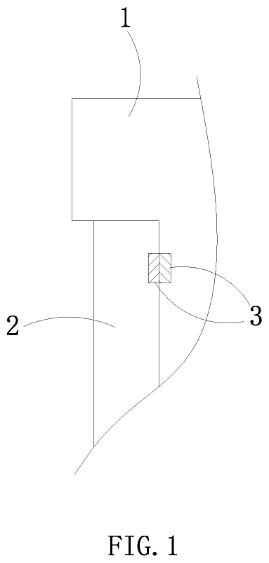

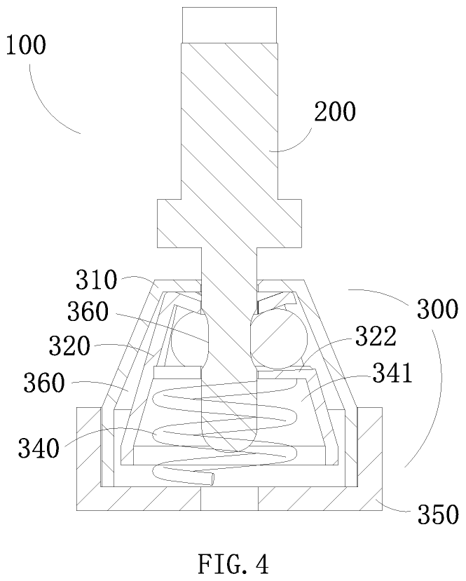

As shown in FIGS. 1 to 7, an LED display screen capable of preventing the display module from accidentally falling off comprises a fixing frame 10 and a plurality of display modules 20.

A removable structure 30 is disposed between each of the display modules 20 and the fixing frame 10.

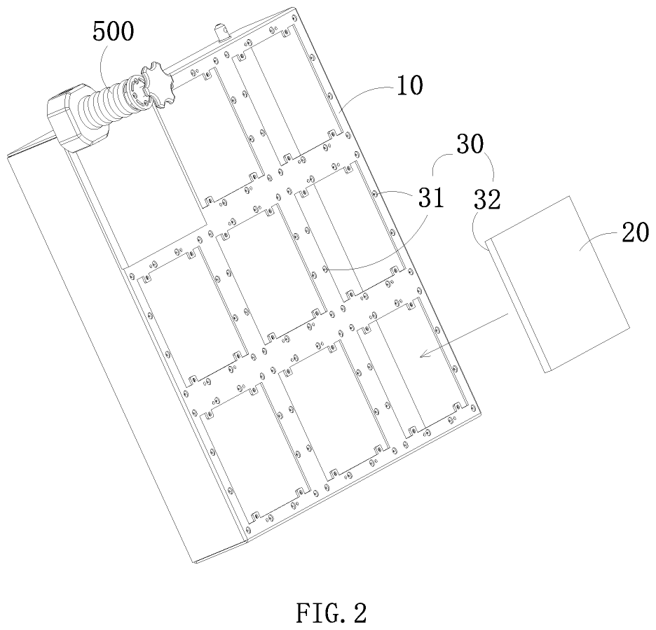

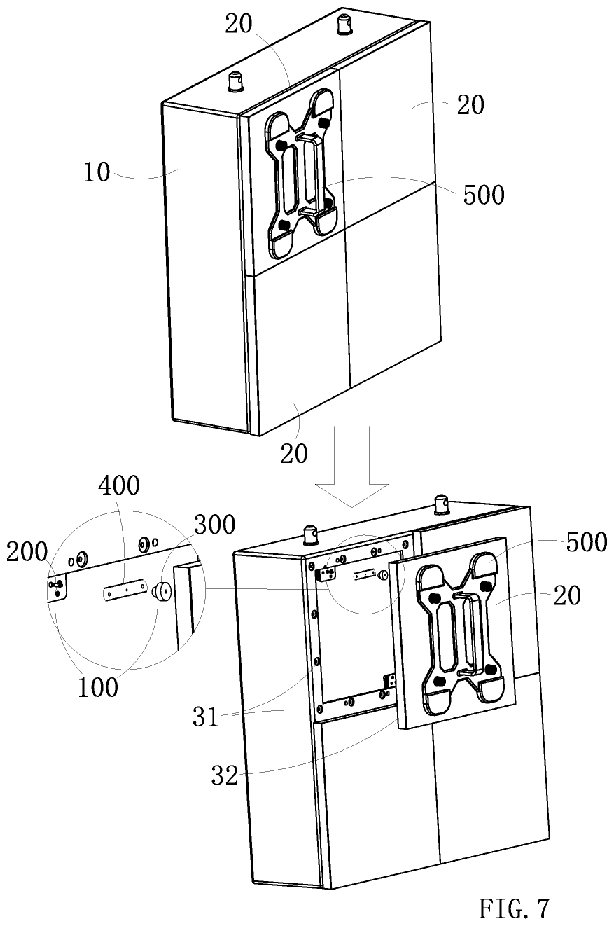

As shown in FIGS. 2 and 7, by the removable structure 30, a plurality of the display modules 20 can be quickly assembled on the fixing frame 10, at the same time, the display module 20 is convenient to be disassembled.

In a specific implementation, the removable structure 30 comprises a fixing frame connector 31 and a module connector 32. The fixing frame connector 31 is disposed on the fixing frame 10, and the module connector 32 is disposed on the display module 20 corresponding to the fixing frame connector 31.

In a specific implementation, the fixing frame connector 31 can be a slot, and the module connector 32 is a post. The holder connector 31 can be a buckle slot, and the module connector 32 is a buckle. Both the fixing frame connector 31 and the module connector 32 may be magnetic blocks.

At the same time, a protection structure 100 is disposed between each of the display modules 20 and the fixing frame 10.

The protection structure 100 can improve the stability of the assembling of the display module 20, and prevent the display module 20 from falling off by the external force.

As shown in FIGS. 2 and 7, in addition, only by some special tools can the protection structure 100 be opened and the display module 20 be removed, and then the display module can be prevented from being stolen

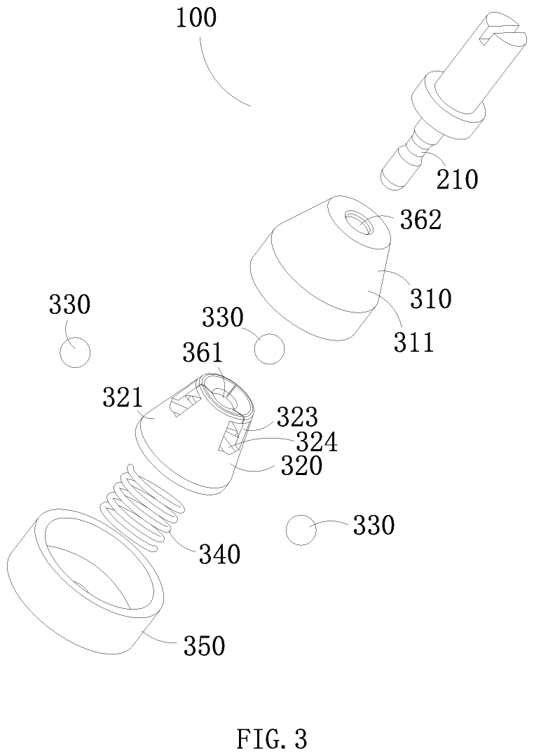

As shown in FIGS. 3, 4, and 6, the protection structure 100 comprises a plug 200 fixed on the fixing frame 10 and a socket 300 fixed on the display module 20, and the plug 200 has a one-to-one correspondence with the socket 300.

As shown in FIG. 7, the protection structure 100 has two states of locking and opening, when the protection structure 100 is In locking state, the plug 200 is inserted into the socket 300, and at this moment, the plug 200 is locked in the socket 300, thereby fixes the relative position between the fixing frame 10 and the display module 20, thus the display module 20 does not accidentally fall off from the fixing frame 10.

When the protection structure 100 is in opening state, the plug 200 is extracted from the socket 300, and at this moment, there is no connection between the plug 200 and the socket 300, and then the display module 20 can be removed from the fixing frame 10 by the removable structure 30, so that realize the easy disassembling.

As shown in FIGS. 3, 4, and 6, the plug 200 is provided with a clamping slot 210.

The socket 300 comprises a casing 310, a marble box 320, a plurality of marbles 330, a spring 340 and a bottom cover 350, wherein the bottom cover 350 is covered at the bottom of the casing 310, thus an action cavity is formed by means of the bottom cover 350 and the casing 310.

The casing 310 has an inclined side wall 311. The marble box 320 is slidably disposed in the action cavity, and has an inclined box side wall 321. In practice, the side wall 321 of the marble box 320 and the side wall 311 of the casing 310 are parallel.

A baffle 322 is disposed in the marble box 320. The box side wall 321 is provided with a plurality of marble holes 323, and provided with a plurality of tracks 324 corresponding to the marble hole 323. One of the marble holes 323 is combined with a corresponded track 324 to form a marble track, and a plurality of the marbles 330 are disposed correspondingly in the marble tracks. A clamping cavity 360 is formed among the plurality of marbles 330, and a box perforation 361 is disposed on the top of the marble box 320 corresponding to the clamping cavity 360, and a casing perforation 362 is provided on the top of the casing 310 corresponding to the clamping cavity 360. The casing perforation 362, the box perforation 361 and the clamping cavity 360 are in communication with each other.

A spring chamber 341 is formed between the baffle 322 and the bottom cover 350, and the spring 340 is disposed in the spring chamber 341.

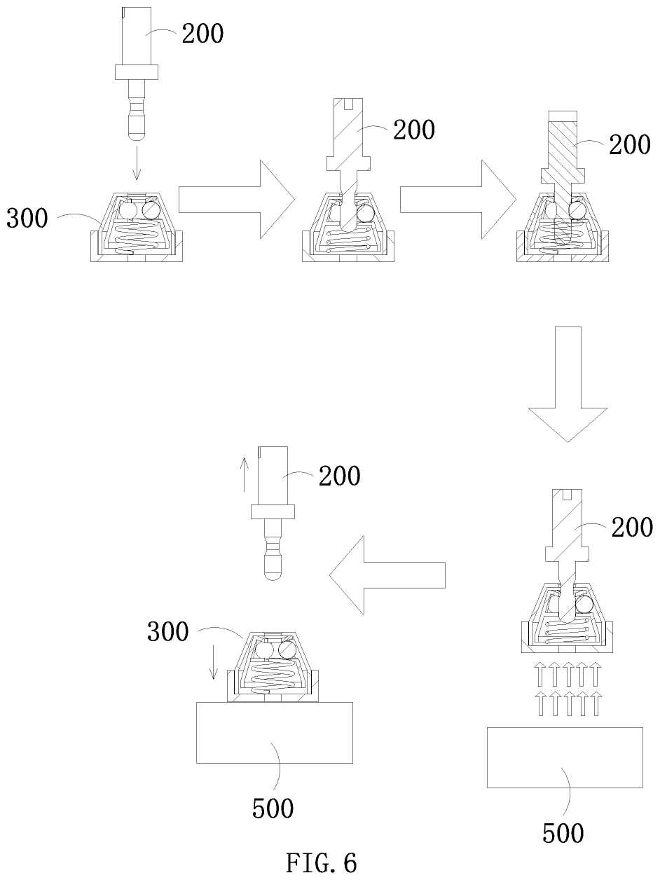

As shown in FIG. 6, when the display module 20 is assembled to the fixing frame 10, the plug 200 sequentially penetrates the casing perforation 362, the box perforation 361, and the clamping cavity 360. When inserting the plug 200 into the clamping cavity 360, the plug 200 simultaneously presses a plurality of the marbles 330 to enlarge the clamping cavity 360, and then the plug 200 continue to insert, when the clamping slot 210 moves to the clamping cavity 360, a plurality of the marbles 330 are simultaneously clamped in the clamping slot 210, at this moment, the clamping cavity 360 is reduced, thereby fixing the relative position between the plug 200 and the socket 300 through a plurality of the marbles 330 and the clamping slot 210, furthermore, the display module 20 is fixed on the fixing frame 10.

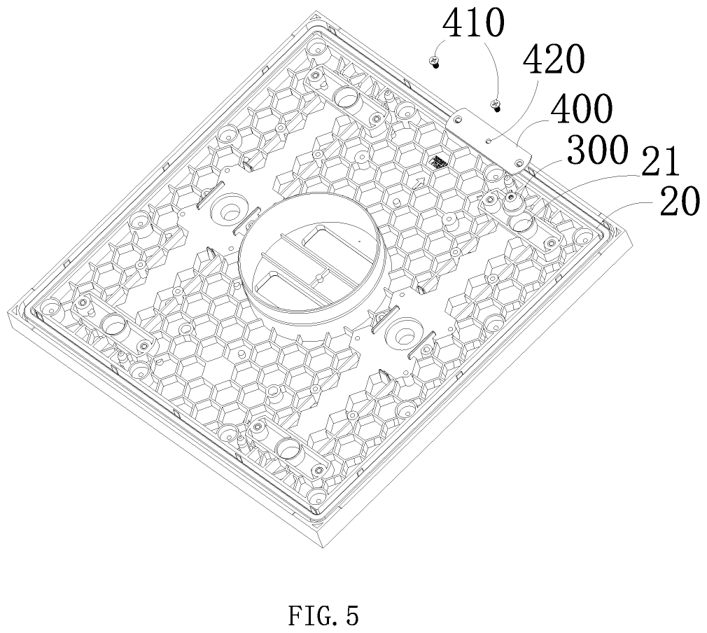

As shown in FIGS. 5 and 7, the protection structure 100 further comprises a magnetic detaching piece 400 and a magnetic detacher 500. The magnetic detaching piece 400 is connected with the socket 300. The magnetic detaching piece 400 and the socket 300 are simultaneously fixed on the display module 20.

As shown in FIGS. 6 and 7, when the display module 20 is removed from the fixing frame 10, the magnetic detacher 500 is adjacent to the display module 20, and at this moment, an opening magnetic force is formed between the magnetic detacher 500 and the socket 300, and a detaching magnetic force is formed between the magnetic detacher 500 and the magnetic detaching piece 400.

The spring 340 provided in the socket 300 is magnetically attracted by the magnetic detacher 500 through the opening magnetic force, and the spring 340 is thereby compressed, at this moment, the clamping cavity 360 is enlarged and released the clamping between the marble 330 and the clamping slot 210, at this moment, the plug 200 can be withdrawn from the socket 300.

At the same time, the magnetic detacher 500 can magnetically fix the display module 20 by the magnetic detaching piece 400 through the detaching magnetic force, and then the display module 20 can be removed from the fixing frame 10.

In the specific implementation, both the magnetic detaching piece 400 and the socket 300 are disposed on the back of the display module 20.

A socket hole 21 is disposed on the back of the display module 20, and the socket 300 is fixed in the socket hole 21.

The magnetic detaching piece 400 is covered on the socket 300, and fixed to the back of the display module 20 by fixing screws 410.

The magnetic detaching piece 400 is provided with a hole 420 which is in communication with the casing perforation 362.

What is claimed is:

1. An LED display screen capable of preventing the display module from accidentally falling off comprising a fixing frame (10) and a plurality of display modules (20), wherein a removable structure (30) is disposed between each of the display module (20) and the fixing frame (10), and the removable structure (30) comprises a fixing frame connector (31) disposed on the fixing frame (10) and a module connector (32) disposed on the display module (20) corresponding to the fixing frame connector (31);
At the same time, a protection structure (100) is disposed between each of the display module (20) and the fixing frame (10), which comprises a plug (200) fixed on the fixing frame (10) and a socket (300) fixed on the display module (20), and the plug (200) has a one-to-one correspondence with the socket (300).

2. An LED display screen according to claim 1, wherein the protection structure (100) has two states of locking and opening, when the protection structure (100) is In locking state, the plug (200) is inserted into the socket (300), and at this moment, the plug (200) is locked in the socket (300), thereby fixes the relative position between the fixing frame (10) and the display module (20), thus the display module (20) does not accidentally fall off from the fixing frame (10), and is prevented from being stolen;
When the protection structure (100) is in opening state, the plug (200) is extracted from the socket (300), and at this moment, there is no connection between the plug (200) and the socket (300), and then the display module (20) can be removed from the fixing frame (10) by the removable structure (30).

3. An LED display screen according to claim 1, wherein both the fixing frame connector (31) and the module connector (32) are magnetic blocks.

4. An LED display screen according to claim 1, wherein the plug (200) is provided with a clamping slot (210), and the socket (300) comprises a casing (310), a marble box (320), a plurality of marbles (330), a spring (340) and a bottom cover (350),
Wherein the bottom cover (350) is covered at the bottom of the casing (310), thus an action cavity is formed by means of the bottom cover (350) and the casing (310);
The casing (310) has an inclined side wall (311);
The marble box (320) is slidably disposed in the action cavity, and has an inclined box side wall (321) which is provided with a plurality of marble holes (323);
A baffle (322) is disposed in the marble box (320), and provided with a plurality of tracks (324) corresponding to the marble hole (323), and one of the marble holes (323) is combined with a corresponded track (324) to form a marble track, and a plurality of the marbles (330) are disposed correspondingly in the marble tracks;
A clamping cavity (360) is formed among the plurality of marbles (330), and a box perforation (361) is disposed on the top of the marble box (320) corresponding to the clamping cavity (360), and a casing perforation (362) is provided on the top of the casing (310) corresponding to the clamping cavity (360);
The casing perforation (362), the box perforation (361) and the clamping cavity (360) are in communication with each other;
A spring chamber (341) is formed between the baffle (322) and the bottom cover (350), and the spring (340) is disposed in the spring chamber (341).

5. An LED display screen according to claim 4, wherein when the display module (20) is assembled to the fixing frame (10), the plug (200) sequentially penetrates the casing perforation (362), the box perforation (361), and the clamping cavity (360).
When being inserted into the clamping cavity (360), the plug (200) simultaneously presses a plurality of the marbles (330) to enlarge the clamping cavity (360), and then the plug (200) continue to insert, when the clamping slot (210) moves to the clamping cavity (360), a plurality of the marbles (330) are simultaneously clamped in the clamping slot (210), at this moment, the clamping cavity (360) is reduced, thereby fixing the relative position between the plug (200) and the socket (300) through a plurality of the marbles (330) and the clamping slot (210), furthermore, the display module (20) is fixed on the fixing frame (10).

6. An LED display screen according to claim 4, wherein the protection structure (100) further comprises a magnetic detaching piece (400),
The magnetic detaching piece (400) is connected with the socket (300), and the magnetic detaching piece (400) and the socket (300) are simultaneously fixed on the display module (20).

7. An LED display screen according to claim 6, wherein the protection structure (100) further comprises a magnetic detacher (500).

8. An LED display screen according to claim 7, wherein when the display module (20) is removed from the fixing frame (10), the magnetic detacher (500) is adjacent to the display module (20), and at this moment, an opening magnetic force is formed between the magnetic detacher (500) and the socket (300), and a detaching magnetic force is formed between the magnetic detacher (500) and the magnetic detaching piece;
The spring (340) provided in the socket (300) is magnetically attracted by the magnetic detacher (500) through the opening magnetic force, and the spring (340) is thereby compressed, at this moment, the clamping cavity (360) is enlarged and released the clamping between the marble (330) and the clamping slot (210), at this moment, the plug (200) can be withdrawn from the socket (300).
At the same time, the magnetic detacher (500) can magnetically fix the display module (20) by the magnetic detaching piece (400) through the detaching magnetic force, and then the display module (20) can be removed from the fixing frame (10).

9. An LED display screen according to claim 4, wherein the side wall (321) of the marble box (320) and the side wall (311) of the casing (310) are parallel.
